(19) United States
(12) Patent Application Publication
(10) Pub. No.: US 2021/0320504 A1
(43) Pub. Date: Oct. 14, 2021

(54) ELECTRONIC DEVICE FOR CONTROLLING CHARGING OF MULTIPLE BATTERIES CONNECTED IN PARALLEL AND METHOD FOR OPERATING SAME

(71) Applicant: Samsung Electronics Co., Ltd., Suwon-si (KR)

(72) Inventors: Hangseok CHOI, Suwon-si (KR); Duhyun KIM, Suwon-si (KR); Seungbeom KANG, Suwon-si (KR); Daeneung KIM, Suwon-si (KR); Gihoon LEE, Suwon-si (KR); Jonghyun LEE, Suwon-si (KR)

(21) Appl. No.: 17/223,363

(22) Filed: Apr. 6, 2021

(30) Foreign Application Priority Data
Apr. 13, 2020 (KR) 10-2020-0044751

(51) Int. Cl. H02J 7/00

(52) U.S. Cl. CPC H02J 7/0014; H02J 7/0047; H02J 7/007182

(57) ABSTRACT

An apparatus and a method of controlling charging of a plurality of batteries connected in parallel in an electronic device are provided. The electronic device includes a charging circuit, a first battery configured to be arranged on a first electrical path connected from the charging circuit to the ground, a second battery configured to be arranged in parallel with the first battery on a second electrical path branched between the charging circuit on the first electrical path and the first battery and connected to the ground, a sensing circuit configured to identify a voltage of the second battery through a fourth electrical path branched on the second electrical path, and a processor operatively connected to the sensing circuit and the charging circuit, the charging circuit identifies a voltage of the first battery through a third electrical path branched on the first electrical path, receives a current control signal based on the voltage of the second battery through the processor, and controls a magnitude of a current supplied to the first battery or the second battery based on the current control signal.

### CROSS-REFERENCE TO RELATED APPLICATION(S)

This application is based on and claims priority under 35 U.S.C. § 119(a) of a Korean patent application number 10-2020-0044751, filed on Apr. 13, 2020, in the Korean Intellectual Property Office, the disclosure of which is incorporated by reference herein in its entirety.

### BACKGROUND

### 1. Field

The disclosure relates to an apparatus and a method for controlling the charging of multiple batteries (for example, battery packs or battery cells) connected in parallel in connection with an electronic device. More particularly, the disclosure relates to an electronic device including a charging circuit, first and second batteries arranged in parallel between the charging circuit and a ground, and a sensing circuit.

### 2. Description of Related Art

In line with development of information/communication technology and semiconductor technology, various electronic devices are evolving into multimedia devices capable of providing various multimedia services. For example, multimedia services may include at least one of a voice call service, a message service, a broadcasting service, a wireless Internet service, a camera service, an electronic payment service, or a music playback service.

Each electronic device employs, as a power source, a battery having a limited power capacity such that the user is afforded portability and mobility. The battery of an electronic device, when used as a power source, enables the user of the electronic device to use the same more conveniently outside the wired environment in which power can be supplied to the electronic device. For example, the electronic device may have multiple batteries (for example, battery packs or battery cells) so as to increase the power capacity. As another example, the battery may include a fuel cell or a secondary battery, which is rechargeable.

The above information is presented as background information only to assist with an understanding of the disclosure. No determination has been made, and no assertion is made, as to whether any of the above might be applicable as prior art with regard to the disclosure.

### SUMMARY

If an electronic device includes a single battery, charging of the battery may be controlled based on the voltage of the battery. For example, if the battery voltage is below a designated voltage (for example, maximum charging voltage), the electronic device (for example, charging circuit) may supply a constant current (CC) to the battery (for example, a CC charging mode). If the battery voltage reaches the designated voltage, the electronic device (for example, charging circuit) may reduce the magnitude of current supplied to the battery (for example, a constant voltage (CV) charging mode).

If the electronic device includes multiples batteries (for example, battery packs or battery cells), it may be difficult to detect the voltage of each battery due to a difference in impedance of the charging path connected to each battery.

Aspects of the disclosure are to address at least the above-mentioned problems and/or disadvantages and to provide at least the advantages described below. Accordingly, as aspect of the disclosure is to provide an apparatus and a method for controlling the charging of multiple batteries (for example, battery packs or battery cells) connected in parallel in connection with an electronic device.

Additional aspects will be set forth in part in the description which follows and, in part, will be apparent from the description, or may be learned by practice of the presented embodiments.

In accordance with an aspect of the disclosure, an electronic device is provided. The electronic device includes a charging circuit, a first battery configured to be arranged on a first electrical path connected from the charging circuit to the ground, a second battery configured to be arranged in parallel with the first battery on a second electrical path branched between the charging circuit and the first battery among the first electrical path and connected to the ground, a sensing circuit configured to identify a voltage of the second battery through a fourth electrical path branched on the second electrical path, and a processor operatively connected to the sensing circuit and the charging circuit. The charging circuit may be configured to identify a voltage of the first battery through a third electrical path branched on the first electrical path, receive a current control signal based on the voltage of the second battery through the processor, and control a magnitude of a current supplied to the first battery and/or the second battery based on the current control signal.

In accordance with another aspect of the disclosure, a method for operating an electronic device is provided. The method includes determining a charging mode of the electronic device based on a voltage of a first battery among the first battery and a second battery connected in parallel through an electrical path, continuously providing a current of a first magnitude through the electrical path when the charging mode of the electronic device is determined to be a first charging mode, and adjusting the magnitude of the current provided through the electrical path to a second magnitude different from the first magnitude when the voltage of the second battery satisfies a designated condition.

In accordance with another aspect of the disclosure, an electronic device is provided. The electronic includes a first battery configured to be arranged on a first electrical path connected from a first charging circuit to the ground, a second battery configured to be arranged in parallel with the first battery on a second electrical path branched between the first charging circuit and the first battery among the first electrical path and connected to the ground, the first charging circuit configured to identify a voltage of the first battery through a third electrical path branched on the first electrical path and to transmit information related to a state of the first battery to a processor when the voltage of the first battery satisfies a designated first condition, a second charging circuit configured to identify a voltage of the second battery through a fourth electrical path branched on the second electrical path and to transmit information related to a state of the second battery to the processor when the voltage of the second battery satisfies a second condition, and a processor operatively connected to the first charging circuit and the second charging circuit. The processor may be configured to provide a current control signal to an external device based on the information related to the state of the first battery and/or the second battery. The second charging circuit may be configured to supply power provided from the external device to the first battery and/or the second battery based on the current control signal.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIG. 2A is a plan view illustrating a front surface of an electronic device in an unfolded state in a first direction according to an embodiment of the disclosure;

FIG. 2B is a plan view illustrating a rear surface of an electronic device in an unfolded state in a first direction according to an embodiment of the disclosure;

FIG. 3A is a perspective view illustrating an electronic device in an unfolded state in a second direction according to an embodiment of the disclosure;

FIG. 3B is a plan view illustrating a front surface of an electronic device in an unfolded state in a second direction according to an embodiment of the disclosure;

FIG. 3C is a plan view illustrating a rear surface of an electronic device in an unfolded state in a second direction according to an embodiment of the disclosure;

FIG. 4 is a block diagram illustrating an electronic device for controlling charging of a battery according to an embodiment of the disclosure;

FIG. 5 is a circuit configuration diagram for controlling charging of a battery according to an embodiment of the disclosure;

FIG. 6 is a flowchart for controlling charging of a battery in an electronic device according to an embodiment of the disclosure;

FIG. 7 is a circuit configuration diagram for controlling charging of a battery through an external device according to an embodiment of the disclosure;

FIG. 8 is a flowchart for controlling charging of a battery through an external device in an electronic device according to an embodiment of the disclosure; and

FIG. 9 is a graph illustrating a state of charge (SOC) of a battery according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

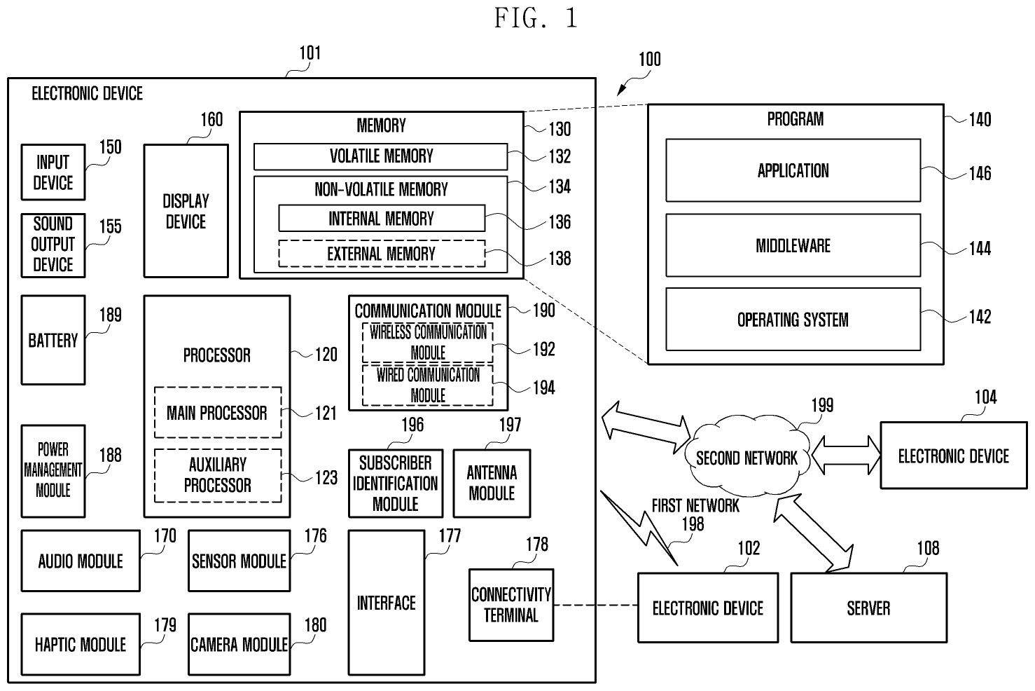

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input device 150, a sound output device 155, a display device 160, an audio module 170, a sensor module 176, an interface 177, a haptic module 179, a camera module 180, a power management module 188, a battery 189, a communication module 190, a subscriber identification module (SIM) 196, or an antenna module 197. In some embodiments, at least one (e.g., the display device 160 or the camera module 180) of the components may be omitted from the electronic device 101, or one or more other components may be added in the electronic device 101. In some embodiments, some of the components may be implemented as single integrated circuitry. For example, the sensor module 176 (e.g., a fingerprint sensor, an iris sensor, or an illuminance sensor) may be implemented as embedded in the display device 160 (e.g., a display).

The processor 120 may execute, for example, software (e.g., a program 140) to control at least one other component (e.g., a hardware or software component) of the electronic device 101 coupled with the processor 120, and may perform various data processing or computation. According to an example embodiment, as at least part of the data processing or computation, the processor 120 may load a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), and an auxiliary processor 123 (e.g., a graphics processing unit (GPU), an image signal processor (ISP), a sensor hub processor, or a communication processor (CP)) that is operable independently from, or in conjunction with, the main processor 121. Additionally or alternatively, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display device 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input device 150 may receive a command or data to be used by another component (e.g., the processor 120) of the electronic device 101, from the outside (e.g., a user) of the electronic device 101. The input device 150 may include, for example, a microphone, a mouse, a keyboard, or a digital pen (e.g., stylus pen).

The sound output device 155 may output sound signals to the outside of the electronic device 101. The sound output device 155 may include, for example, a speaker or a receiver. The speaker may be used for general purposes, such as playing multimedia or playing record, and the receiver may be used for incoming calls. According to an embodiment, the receiver may be implemented as separate from, or as part of the speaker.

The display device 160 may visually provide information to the outside (e.g., a user) of the electronic device 101. The display device 160 may include, for example, a display, a hologram device, or a projector and control circuitry to control a corresponding one of the display, hologram device, and projector. According to an embodiment, the display device 160 may include touch circuitry adapted to detect a touch, or sensor circuitry (e.g., a pressure sensor) adapted to measure the intensity of force incurred by the touch.

The audio module 170 may convert a sound into an electrical signal and vice versa. According to an embodiment, the audio module 170 may obtain the sound via the input device 150, or output the sound via the sound output device 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting (or connectivity) terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an example embodiment, the power management module 188 may be implemented as at least part of, for example, a power management integrated circuit (PMIC).

The battery 189 may supply power to at least one component of the electronic device 101. According to an embodiment, the battery 189 may include, for example, a non-rechargeable primary cell, a rechargeable secondary cell, or a fuel cell. According to an embodiment, the battery 189 may include a plurality of battery packs or cells of a battery.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, Wi-Fi direct, or infrared data association (IrDA)) or the second network 199 (e.g., a long-range communication network, such as a cellular network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., PCB). According to an embodiment, the antenna module 197 may include a plurality of antennas. In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the external electronic devices 102 and 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, or client-server computing technology may be used, for example.

The electronic device according to certain embodiments may be one of various types of electronic devices. The electronic devices may include, for example, a portable communication device (e.g., a smart phone), a computer device, a portable multimedia device, a portable medical device, a camera, a wearable device, or a home appliance. According to an embodiment of the disclosure, the electronic devices are not limited to those described above.

It should be appreciated that certain embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively,” as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry.” A module may be a single integral component, or a minimum unit or part thereof, adapted to perform one or more functions. For example, according to an embodiment, the module may be implemented in a form of an application-specific integrated circuit (ASIC).

Certain embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. The term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to certain embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to certain embodiments, each component (e.g., a module or a program) of the above-described components may include a single entity or multiple entities. According to certain embodiments, one or more of the above-described components may be omitted, or one or more other components may be added. Alternatively or additionally, a plurality of components (e.g., modules or programs) may be integrated into a single component. In such a case, according to certain embodiments, the integrated component may still perform one or more functions of each of the plurality of components in the same or similar manner as they are performed by a corresponding one of the plurality of components before the integration. According to certain embodiments, operations performed by the module, the program, or another component may be carried out sequentially, in parallel, repeatedly, or heuristically, or one or more of the operations may be executed in a different order or omitted, or one or more other operations may be added.

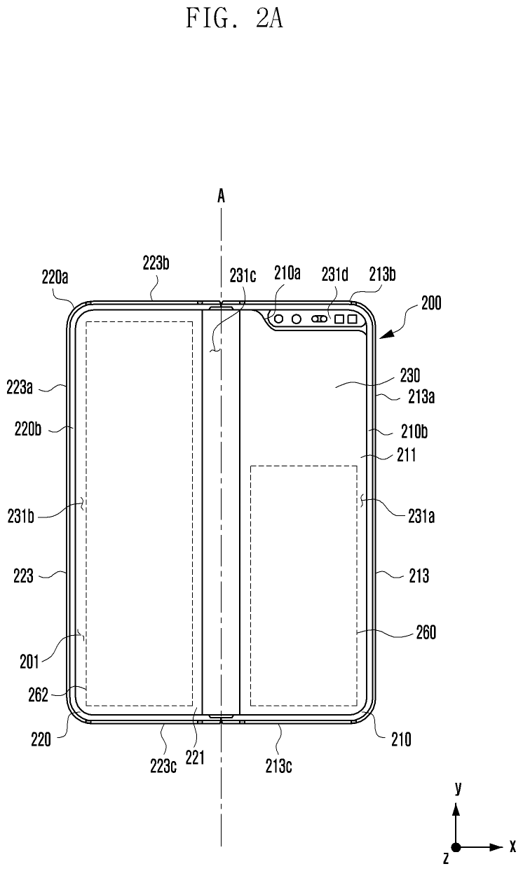

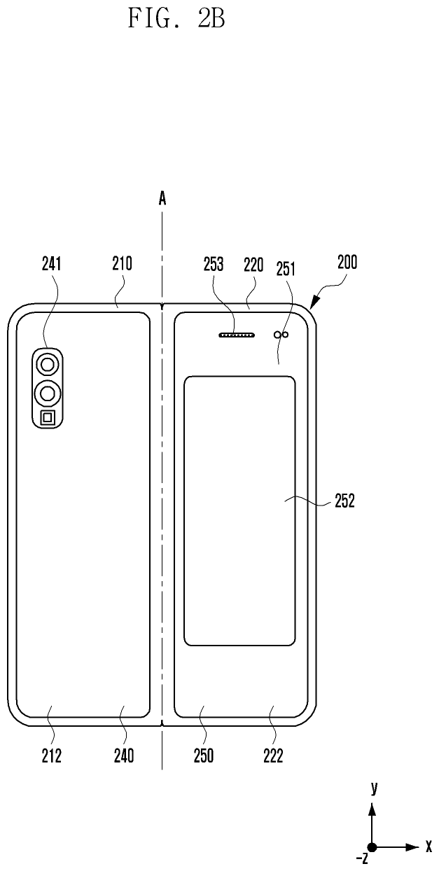

FIG. 2A is a plan view illustrating a front surface of an electronic device 200 in a flat stage or unfolded state in a first direction according to an embodiment of the disclosure.

FIG. 2B is a plan view illustrating a rear surface of the electronic device 200 in a flat stage or an unfolded state in a first direction according to an embodiment of the disclosure. For example, the electronic device 200 of FIGS. 2A and 2B may be at least partially similar to the electronic device 101 of FIG. 1, or may include another embodiment of the electronic device.

Referring to FIGS. 2A and 2B, the electronic device 200 may include a pair of housing structures 210 and 220 (e.g., a foldable housing structure) that are rotatably coupled to each other through a hinge structure so that they are folded with respect to each other, a hinge cover that covers a foldable portion of the pair of housing structures 210 and 220, and a display 230 (e.g., a flexible display, a foldable display, or a first display) that is arranged in a space disposed by the pair of housing structures 210 and 220. In this document, a surface on which the display 230 is arranged may be defined as a front surface of the electronic device 200, and a surface opposite the front surface may be defined as a rear surface of the electronic device 200. Also, a surface surrounding a space between the front and rear surfaces may be defined as a side surface of the electronic device 200.

In an embodiment, the pair of housing structures 210 and 220 may include a first housing structure 210 including a sensor area 231d, a second housing structure 220, a first rear cover 240, and a second rear cover 250. The pair of housing structures 210 and 220 of the electronic device 200 are not limited to the shapes and combinations shown in FIGS. 2A and 2B, and may be implemented by the combination and/or coupling of other shapes or components. For example, in another embodiment, the first housing structure 210 and the first rear cover 240 may be integrally formed, and the second housing structure 220 and the second rear cover 250 may be integrally formed.

According to an embodiment, the first housing structure 210 and the second housing structure 220 may be arranged on both sides around a folding axis (A axis), and may have a shape that is generally symmetric with respect to the folding axis (A axis). According to an embodiment, the first housing structure 210 and the second housing structure 220 may have different angles or distances therebetween depending on whether the electronic device 200 is in a flat stage or unfolded state, a folded state, or an intermediate state. According to an embodiment, unlike the second housing structure 220, the first housing structure 210 may additionally include the sensor area 231d in which various sensors are arranged, but may have a mutually symmetric shape in other areas. In another embodiment, the sensor area 231d may be additionally arranged or replaced in at least a partial area of the second housing structure 220.

In an embodiment, the first housing structure 210 may be connected to the hinge structure in the unfolded state of the electronic device 200, and may include a first surface 211 arranged to face the front surface of the electronic device 200, a second surface 212 arranged to face the opposite direction of the first surface 211, and a first side member 213 surrounding at least a portion of a space between the first surface 211 and the second surface 212. In an embodiment, the first side member 213 may include a first side surface 213a arranged parallel to the folding axis (A axis), a second side surface 213b extending in a direction perpendicular to the folding axis from one end of the first side surface 213a, and a third side surface 213c extending in a direction perpendicular to the folding axis (A axis) from the other end of the first side surface 213a.

In an embodiment, the second housing structure 220 may be connected to the hinge structure in the unfolded state of the electronic device 200, and may include a third surface 221 arranged to face the front surface of the electronic device 200, a fourth surface 222 facing the opposite direction of the third surface 221, and a second side member 223 surrounding at least a portion of a space between the third surface 221 and the fourth surface 222. In an embodiment, the second side surface 223 may include a fourth side surface 223a arranged parallel to the folding axis (A axis), a fifth side surface 223b extending in a direction perpendicular to the folding axis (A axis) from one end of the fourth side surface 223a, and a sixth side surface 223c extending in a direction perpendicular to the folding axis (A axis) from the other end of the fourth side surface 223a. In an embodiment, the third surface 221 may face the first surface 211 in a folded state.

In an embodiment, the electronic device 200 may include a recess 201 formed to receive the display 230 through a structural combination of the first housing structure 210 and the second housing structure 220. The recess 201 may have substantially the same size as the display 230. In an embodiment, due to the sensor area 231d, the recess 201 may have two or more different widths in a direction perpendicular to the folding axis (A axis). In an embodiment, a first portion 210a and a second portion 210b of the first housing structure 210 may be formed to have different distances from the folding axis (A axis). In an embodiment, a third portion 220a and a fourth portion 220b of the second housing structure 220 may be formed to have different distances from the folding axis (A axis). The width of the recess 201 is not limited to the illustrated example. In various embodiments, the recess 201 may have two or more different widths due to the shape of the sensor area 231d or a portion having an asymmetric shape of the first and second housing structures 210 and 220.

In an embodiment, at least a portion of the first housing structure 210 and the second housing structure 220 may be made of a metal material or a non-metal material having a rigidity of a size selected to support the display 230.

In an embodiment, the sensor area 231d may be formed to have a predetermined area adjacent to one corner of the first housing structure 210. However, the arrangement, shape, or size of the sensor area 231d is not limited to the illustrated example. For example, in another embodiment, the sensor area 231d may be provided at another corner of the first housing structure 210 or in an arbitrary area between the upper and lower corners thereof. In another embodiment, the sensor area 231d may be arranged on at least a partial area of the second housing structure 220. In another embodiment, the sensor area 231d may be arranged to extend from the first housing structure 210 and the second housing structure 220. In an embodiment, the electronic device 200 may have various components for performing various functions which are arranged to be exposed to the front surface of the electronic device 200 through the sensor area 231d or one or more openings provided in the sensor area 231d. In various embodiments, the components may include at least one of a front camera device, a receiver, a proximity sensor, an illuminance sensor, an iris recognition sensor, an ultrasonic sensor, or an indicator.

In an embodiment, the first rear cover 240 may be arranged on the second surface 212 of the first housing structure 210 and may have a substantially rectangular periphery. In an embodiment, at least a portion of the periphery may be wrapped by the first housing structure 210. Similarly, the second rear cover 250 may be arranged on the fourth surface 222 of the second housing structure 220, and at least a portion of the periphery of the second rear cover 250 may be wrapped by the second housing structure 220.

In the illustrated embodiment, the first rear cover 240 and the second rear cover 250 may have a substantially symmetrical shape with respect to the folding axis (A axis). In another embodiment, the first rear cover 240 and the second rear cover 250 may have various different shapes. In another embodiment, the first rear cover 240 may be integrally formed with the first housing structure 210, and the second rear cover 250 may be integrally formed with the second housing structure 220.

In an embodiment, the first rear cover 240, the second rear cover 250, the first housing structure 210, and the second housing structure 220 may provide a space where various components (e.g., a printed circuit board, an antenna module, a sensor module, a battery, etc.) of the electronic device 200 can be arranged through a structure in which they are coupled to one another. In an embodiment, one or more components may be arranged on the rear surface of the electronic device 200 or may be visually exposed. For example, one or more components or sensors may be visually exposed through a first rear area 241 of the first rear cover 240. In various embodiments, the sensor may include a proximity sensor, a rear camera device, and/or a flash. In another embodiment, at least a portion of a sub-display 252 (e.g., the second display) may be visually exposed through a second rear area 251 of the second rear cover 250. In another embodiment, the electronic device 200 may include a speaker module 253 arranged through at least a partial area of the second rear cover 250.

The display 230 may be arranged on a space disposed by the pair of housing structures 210 and 220. For example, the display 230 may be seated in the recess 201 formed by the pair of housing structures 210 and 220, and may be arranged to occupy substantially most of the front surface of the electronic device 200. Accordingly, the front surface of the electronic device 200 may include the display 230, a partial area (e.g., a peripheral area) of the first housing structure 210 adjacent to the display 230, and a partial area (e.g., a peripheral area) of the second housing structure 220 adjacent to the display 230. In an embodiment, the rear surface of the electronic device 200 may include the first rear cover 240, a partial area (e.g., a peripheral area) of the first housing structure 210 adjacent to the first rear cover 240, the second rear cover 250, and a partial area (e.g., a peripheral area) of the second housing structure 220 adjacent to the second rear cover 250.

In an embodiment, the display 230 may refer to a display of which at least partial area can be transformed into a flat or curved surface. In an embodiment, the display 230 may include a folding area 231c, a first area 231a arranged on one side (e.g., a right area of the folding area 231c) with respect to the folding area 231c, and a second area 231b arranged on the other side (e.g., a left area of the folding area 231c). For example, the first area 231a may be arranged on the first surface 211 of the first housing structure 210, and the second area 231b may be arranged on the third surface 221 of the second housing structure 220. In an embodiment, the division of the area of the display 230 is exemplary, and the display 230 may be divided into a plurality of (e.g., four or more or two) areas according to the structure or function thereof. For example, in the embodiment shown in FIGS. 2A and 2B, the area of the display 230 may be divided by the folding area 231c extending parallel to the y-axis or the folding axis (A-axis), but in another embodiment, the area of the display 230 may be divided with respect to another folding area (e.g., a folding area parallel to the x-axis) or another folding axis (e.g., a folding axis parallel to the x-axis). The above-described division of the area of the display is only physical division by the pair of housing structures 210 and 220 and the hinge structure. As for the display 230, one full screen can be displayed substantially through the pair of housing structures 210 and 220 and the hinge structure. In an embodiment, the first area 231a and the second area 231b may have a shape symmetrical to each other as a whole with respect to the folding area 231c. However, unlike the second area 231b, the first area 231a may include a notch area that is cut according to the presence of the sensor area 231d, but in the other areas, the first area 231a may have a shape symmetrical to the second area 231b. For example, the first area 231a and the second area 231b may include a portion having a shape symmetrical to each other and a portion having a shape asymmetrical to each other.

According to various embodiments, the electronic device 200 may include a first battery 260 (e.g., a battery pack or a cell of a battery) positioned in at least a portion of the first housing structure 210 and a second battery 262 (e.g., a battery pack or a cell of a battery) positioned in at least a portion of the second housing structure 220. According to an embodiment, the first battery 260 and the second battery 262 may be connected in parallel. For example, at least one of the type or capacity (or maximum capacity) of the first battery 260 and the second battery 262 may be the same or different.

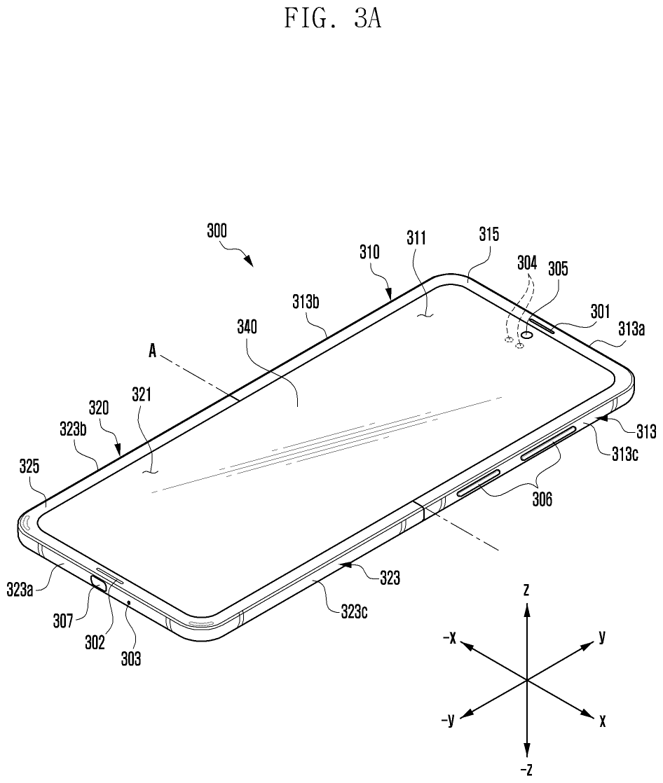

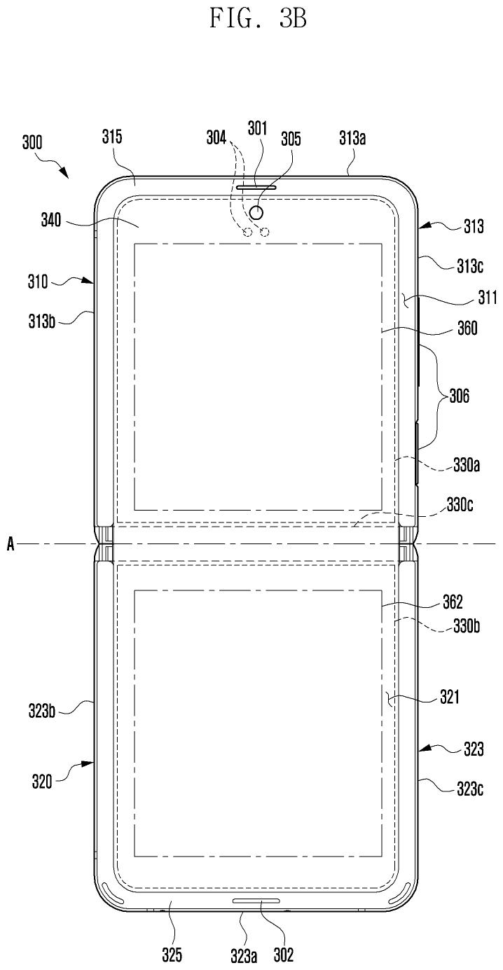

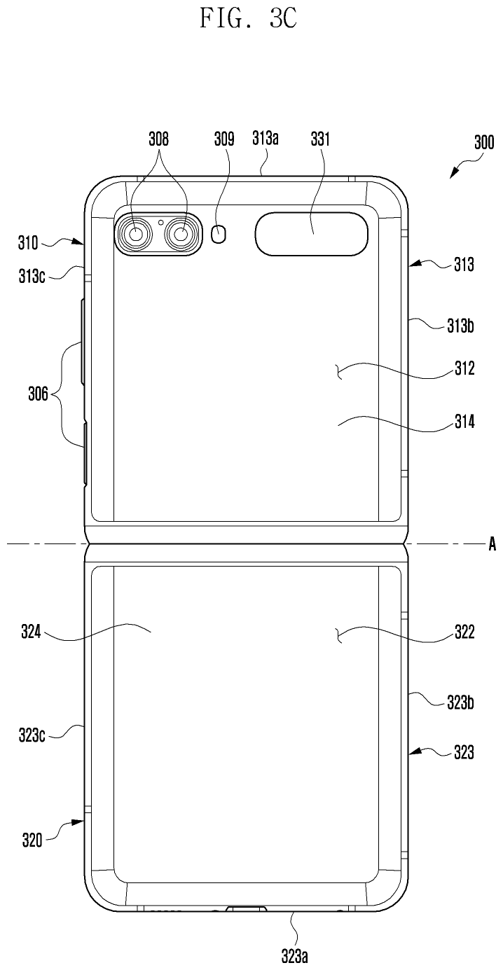

FIG. 3A is a perspective view illustrating an electronic device 300 in an unfolded state in a second direction according to an embodiment of the disclosure, FIG. 3B is a plan view illustrating a front surface of the electronic device 300 in an unfolded state in a second direction according to an embodiment of the disclosure, and FIG. 3C is a plan view illustrating a rear surface of the electronic device 300 in an unfolded state in a second direction according to an embodiment of the disclosure. For example, the electronic device 300 of FIGS. 3A, 3B, and 3C may be at least partially similar to the electronic device 101 of FIG. 1, or may include another embodiment of the electronic device.

Referring to FIGS. 3A, 3B, and 3C, the electronic device 300 may include a pair of housings 310 and 320 (e.g., foldable housings) that are rotatably coupled so as to be folded while facing each other with respect to a hinge module. According to an embodiment, the electronic device 300 may include a flexible display 340 (e.g., a foldable display) arranged in an area formed by the pair of housings 310 and 320. According to an embodiment, the first housing 310 and the second housing 320 may be arranged on both sides with respect to a folding axis (axis A), and may have a substantially symmetrical shape with respect to the folding axis (axis A). According to an embodiment, the first housing 310 and the second housing 320 may have different angles or distances therebetween depending on whether the electronic device 300 is in a flat stage or unfolded state, a folded state, or an intermediate state.

According to various embodiments, the pair of housings 310 and 320 may include a first housing 310 (e.g., a first housing structure) coupled to the hinge module and a second housing 320 (e.g., a second housing structure) coupled to the hinge module. According to an embodiment, in the unfolded state, the first housing 310 may include a first surface 311 facing a first direction (e.g., a front direction) (z-axis direction) and a second surface 312 opposite the first surface 311 and facing a second direction (e.g., a rear direction) (−z-axis direction). According to an embodiment, in the unfolded state, the second housing 320 may include a third surface 321 facing the first direction (z-axis direction) and a fourth surface 322 facing the second direction (−z-axis direction). According to an embodiment, the electronic device 300 may operate in a manner that the first surface 311 of the first housing 310 and the third surface 321 of the second housing 320 face substantially the same first direction (z-axis direction) in the unfolded state and the first surface 311, and the third surface 321 face each other in the folded state. According to an embodiment, the electronic device 300 may operate in a manner that the second surface 312 of the first housing 310 and the fourth surface 322 of the second housing 320 face substantially the same second direction (−z-axis direction) in the unfolded state, and the second surface 312 and the fourth surface 322 face opposite directions in the folded state. For example, in the folded state, the second surface 312 may face the first direction (z-axis direction) and the fourth surface 322 may face the second direction (−z-axis direction).

According to various embodiments, the first housing 310 may include a first side frame 313 that at least partially forms the exterior of the electronic device 300 and a first rear cover 314 that is couple to the first side frame 313 and forms at least a portion of the second surface 312 of the electronic device 300. According to an embodiment, the first side frame 313 may include a first side surface 313a that is substantially parallel to a folding axis (e.g., axis A), a second side surface 313b that extends from one end of the first side surface 313a, and a third side surface 313c that extends from the other end of the first side surface 313a. According to an embodiment, the first side frame 313 may be formed in a rectangular shape (e.g., square or rectangular) through the first side surface 313a, the second side surface 313b, and the third side surface 313c.

According to various embodiments, the second housing 320 may include a second side frame 323 that at least partially forms the exterior of the electronic device 300 and a second rear cover 324 that is coupled to the second side frame 323 and forms at least a portion of the fourth surface 322 of the electronic device 300. According to an embodiment, the second side frame 323 may include a fourth side surface 323a that is substantially parallel to the folding axis (e.g., axis A), a fifth side surface 323b that extends from one end of the fourth side surface 323a, and a sixth side surface 323c that extends from the other end of the fourth side surface 323a. According to an embodiment, the second side frame 323 may be formed in a rectangular shape through the fourth side surface 323a, the fifth side surface 323b, and the sixth side surface 323c.

According to various embodiments, the pair of housings 310 and 320 are not limited to the illustrated shape and combination, and may be implemented by the combination and/or coupling of other shapes or components. For example, the first side frame 313 may be integrally formed with the first rear cover 314, and the second side frame 323 may be integrally formed with the second rear cover 324.

According to various embodiments, as for the electronic device 300, in the unfolded state, the second side surface 313b of the first side frame 313 and the fifth side surface 323b of the second side frame 323 may be connected to each other without any gap therebetween. According to an embodiment, as for the electronic device 300, in the unfolded state, the third side surface 313c of the first side frame 313 and the sixth side surface 323c of the second frame 323 may be connected to each other without any gap therebetween. According to an embodiment, in the unfolded state, the electronic device 300 may be configured in a manner that the combined length of the second side surface 313b and the fifth side surface 323b is longer than the length of the first side surface 313a and/or the fourth side surface 323a. In addition, the electronic device 300 may be configured in a manner that the combined length of the third side surface 313c and the sixth side surface 323c is longer than the length of the first side surface 313a and/or the fourth side surface 323a.

According to various embodiments, the flexible display 340 may be arranged to extend from the first surface 311 of the first housing 310 to at least a portion of the third surface 321 of the second housing 320 across the hinge module. For example, the flexible display 340 may include a first flat portion 330a substantially corresponding to the first surface 311, a second flat portion 330b corresponding to the third surface 321, and a bendable portion 330c connecting the first flat portion 330a and the second flat portion 330b and corresponding to the hinge module. According to an embodiment, the electronic device 300 may include a first protective cover 315 (e.g., a first protective frame or a first decorative member) coupled along an edge of the first housing 310. According to an embodiment, the electronic device 300 may include a second protective cover 325 (e.g., a second protective frame or a second decorative member) coupled along an edge of the second housing 320. According to an embodiment, the flexible display 340 may be positioned such that an edge of the first flat portion 330a is interposed between the first housing 310 and the first protective cover 315. According to an embodiment, the flexible display 340 may be positioned such that an edge of the second flat portion 330b is interposed between the second housing 320 and the second protective cover 325. According to an embodiment, the flexible display 340 may be positioned so that an edge of the flexible display 340 corresponding to a protective cap is protected through the protective cap disposed in an area corresponding to the hinge module. Accordingly, the edge of the flexible display 340 may be substantially protected from the outside. According to an embodiment, the electronic device 300 may include a hinge housing (e.g., a hinge cover) that supports the hinge module and is arranged to be exposed to the outside when the electronic device 300 is in the folded state and to be introduced into a first space and a second space when the electronic device 300 is in the unfolded state so that the hinge housing is not visible from the outside.

According to various embodiments, the electronic device 300 may include a sub-display 331 arranged separately from the flexible display 340. According to an embodiment, the sub-display 331 may be arranged so as to be at least partially exposed to the outside on the second surface 312 of the first housing 310, so that the sub-display 331 may display, in the unfolded state, state information of the electronic device 300 that replaces a display function of the flexible display 340. According to an embodiment, the sub-display 331 may be arranged to be visible from the outside through at least a partial area of the first rear cover 314. According to an embodiment, the sub-display 331 may be arranged on the fourth surface 322 of the second housing 320. In this case, the sub-display 331 may be arranged to be visible from the outside through at least a partial area of the second rear cover 324.

According to various embodiments, the electronic device 300 may include a first battery 360 (e.g., a battery pack or a cell of a battery) positioned in at least a portion of the first housing 310 and a second battery 362 (e.g., a battery pack or a cell of a battery) positioned in at least a portion of the second housing 320. According to an embodiment, the first battery 360 and the second battery 362 may be connected in parallel. For example, at least one of the type or capacity (or maximum capacity) of the first battery 360 and the second battery 362 may be the same or different.

According to various embodiments, the electronic device 300 may include at least one of an input device 303 (e.g., a microphone), sound output devices 301 and 302, a sensor module 304, camera devices 305 and 308, and a key input device 306, or a connector port 307. In the illustrated embodiment, the input device 303 (e.g., a microphone), the sound output devices 301 and 302, the sensor module 304, the camera devices 305 and 308, the key input device 306, or the connector port 307 may refer to holes or shapes formed on the first housing 310 or the second housing 320, but may be defined to include substantial electronic components (input device, sound output device, sensor module, or camera device) which are arranged inside the electronic device 300 and operate through the holes or shapes.

According to various embodiments, the input device 303 may include at least one microphone arranged in the second housing 320. According to an embodiment, the input device 303 may include a plurality of microphones arranged to detect the direction of sound. According to an embodiment, the plurality of microphones may be arranged at appropriate positions in the first housing 310 and/or the second housing 320.

According to various embodiments, the sound output devices 301 and 302 may include at least one speaker. According to an embodiment, the speakers may include a first sound output device 301 (e.g., a call receiver) arranged in the first housing 310 and a second sound output device 302 (e.g., a speaker) arranged in the second housing 320. According to an embodiment, the input device 303, the sound output devices 301 and 302, and the connector port 307 may be arranged in spaces provided in the first housing 310 and/or the second housing 320 of the electronic device 300, and may be exposed to an external environment through at least one hole formed in the first housing 310 and/or the second housing 320. According to an embodiment, at least one connector port 307 may be used to transmit and receive power and/or data to and from an external electronic device. In some embodiments, the at least one connector port (e.g., an ear jack hole) may accommodate a connector (e.g., an ear jack) for transmitting and receiving an audio signal to and from the external electronic device. According to an embodiment, the holes formed in the first housing 310 and/or the second housing 320 may be commonly used for the input device 303 and the sound output devices 301 and 302. According to an embodiment, the sound output devices 301 and 302 may include a speaker (e.g., a piezo speaker) operated while the holes formed in the first housing 310 and/or the second housing 320 are excluded.

According to various embodiments, the sensor module 304 may generate an electrical signal or data value corresponding to an internal operating state of the electronic device 300 or an external environmental state. According to an embodiment, the sensor module 304 may detect an external environment through the first surface 311 of the first housing 310. According to an embodiment, the electronic device 300 may further include at least one sensor module arranged to detect the external environment through the second surface 312 of the first housing 310. According to an embodiment, the sensor module 304 (e.g., an illuminance sensor) may be arranged under the flexible display 340 to detect the external environment through the flexible display 340. According to an embodiment, the sensor module 304 may include at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, an illuminance sensor, a proximity sensor, an ultrasonic sensor, or an illuminance sensor.

According to various embodiments, the camera devices 305 and 308 may include a first camera device 305 (e.g., a front camera device) arranged on the first surface 311 of the first housing 310 and a second camera device 308 arranged on the second surface 312 of the first housing 310. The electronic device 300 may further include a flash 309 arranged near the second camera device 308. According to an embodiment, the camera devices 305 and 308 may include one or a plurality of lenses, an image sensor, and/or an image signal processor. For example, the flash 309 may include a light emitting diode or a xenon lamp. According to an embodiment, as for the camera devices 305 and 308, two or more lenses (e.g., a wide-angle lens, an ultra-wide-angle lens, or a telephoto lens) and image sensors may be arranged to be positioned on one surface (e.g., the first surface 311, the second surface 312, the third surface 321, or the fourth surface 322) of the electronic device 300. In some embodiments, the camera devices 305 and 308 may include lenses for time of flight (TOF) and an image sensor.

According to various embodiments, the key input device 306 (e.g., a key button) may be arranged on the third side surface 313c of the first side frame 313 of the first housing 310. In some embodiments, the key input device 306 may be arranged on at least one side surface of the other side surfaces 313a and 313b of the first housing 310 and/or the side surfaces 323a, 323b, and 323c of the second housing 320. In some embodiments, the electronic device 300 may not include some or all of the key input devices 306 and the key input device 306 that is not included in the electronic device 300 may be implemented in another form such as soft keys on the flexible display 340. In some embodiments, the key input device 306 may be implemented using a pressure sensor included in the flexible display 340.

According to various embodiments, some camera devices 305 of the camera devices 305 and 308 or the sensor module 304 may be arranged to be exposed through the flexible display 340. For example, the first camera device 305 or the sensor module 304 may be arranged to contact the external environment through an opening (e.g., a through-hole) at least partially formed in the flexible display 340 in the internal space of the electronic device 300. In another embodiment, some sensor modules 304 may be arranged to perform their functions without being visually exposed through the flexible display 340 in the internal space of the electronic device 300. For example, in this case, an area of the flexible display 340 that faces the sensor module 304 may not need to have an opening.

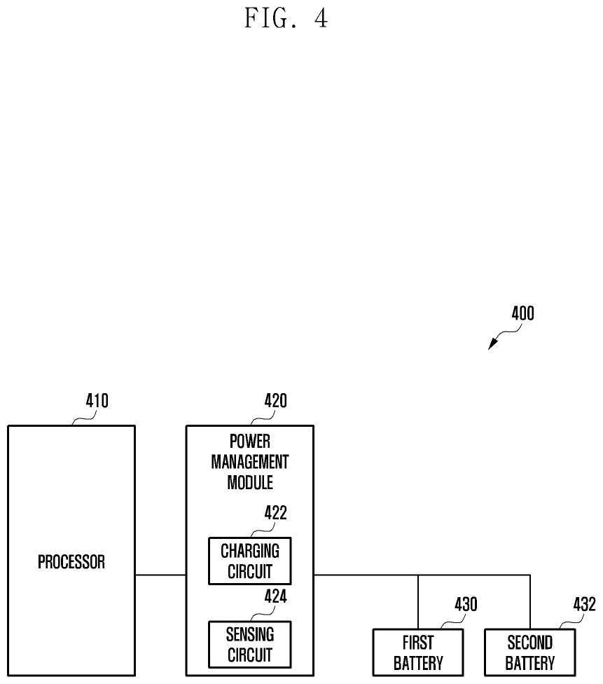

FIG. 4 is a block diagram illustrating an electronic device 400 for controlling charging of a battery according to an embodiment of the disclosure. As an example, the electronic device 400 of FIG. 4 may include at least partially similar embodiments to the electronic device 101 of FIG. 1, the electronic device 200 of FIGS. 2A and 2B, or the electronic device 300 of FIGS. 3A, 3B, and 3C, or may include other embodiments of the electronic device.

Referring to FIG. 4, the electronic device 400 may include a processor 410, a power management module 420, a first battery 430, and/or a second battery 432. According to an embodiment, the first battery 430 and/or the second battery 432 may be substantially the same as the battery 189 of FIG. 1, or may be included in the battery 189. The power management module 420 may be substantially the same as the power management module 188 of FIG. 1, or may be included in the power management module 188. The processor 410 may be substantially the same as the processor 120 of FIG. 1, or may be included in the processor 120.

According to various embodiments, the first battery 430 and/or the second battery 432 may be connected in parallel. According to an embodiment, the first battery 430 and the second battery 432 may have the same and/or different types and/or capacity (or maximum capacity). As an example, the second battery 432 may be configured to have a relatively larger or equal capacity than the first battery 430.

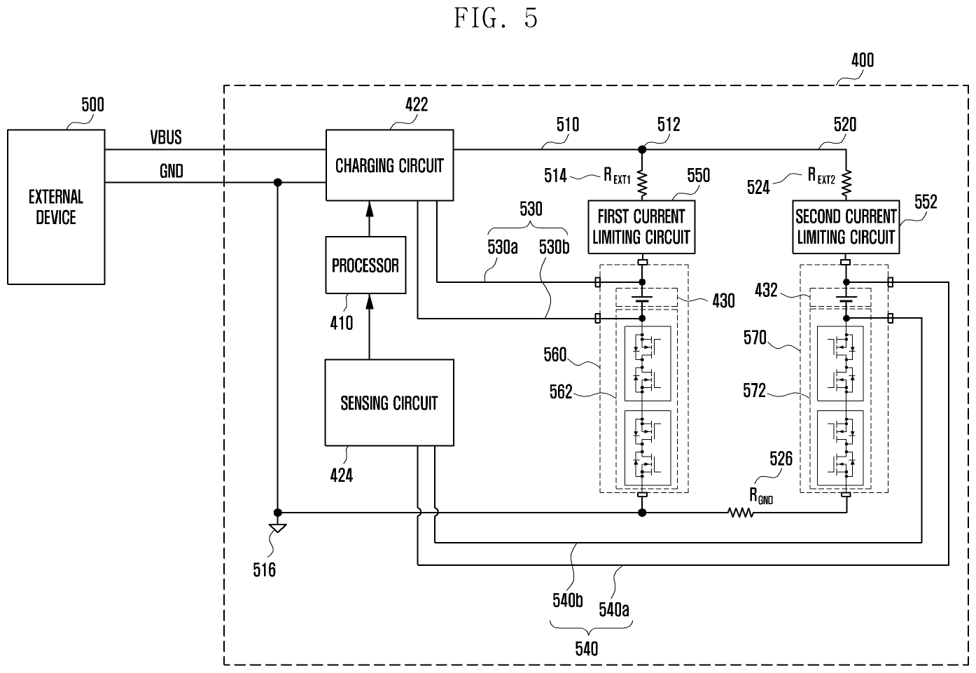

According to various embodiments, the power management module 420 may include a charging circuit 422 and/or a sensing circuit 424. According to an embodiment, the charging circuit 422 may supply the first battery 430 and/or the second battery 432 with power supplied from an external power source. For example, the charging circuit 422 may configure a charging mode of the electronic device 400 to be a constant current (CC) charging mode or a constant voltage (CV) charging mode based on the voltage of the first battery 430. As an example, when the voltage of the first battery 430 is less than a first designated voltage, the charging circuit 422 may configure the charging mode of the electronic device 400 to be the CC charging mode to supply the first battery 430 and/or the second battery 432 with a current (constant current (CC)) having a designated magnitude. As an example, when the voltage of the first battery 430 reaches the first designated voltage, the charging circuit 422 may switch the charging mode of the electronic device 400 to the CV charging mode to reduce the magnitude of the current supplied to the first battery 430 and/or the second battery 432. As an example, the first designated voltage may include a reference voltage for determining a time point of switching the charging mode of the first battery 430 or a maximum charging voltage of the first battery 430. For example, the charging circuit 422 may detect the voltage of the first battery 430 through an electrical path connected to the first battery 430 (e.g., a third electrical path 530 in FIG. 5). For example, the charging circuit 422 may adjust the magnitude of the current (e.g., the magnitude of CC) that provides the first battery 430 and/or the second battery 432 based on a first control signal for controlling a charging current provided from the processor 410 while the charging circuit 422 is driven in the CC charging mode. For example, the CC charging may be maintained for the first battery 430, and the second battery 432 may be reduced by a reduced level designated as the amount of a current at which constant voltage charging can proceed.

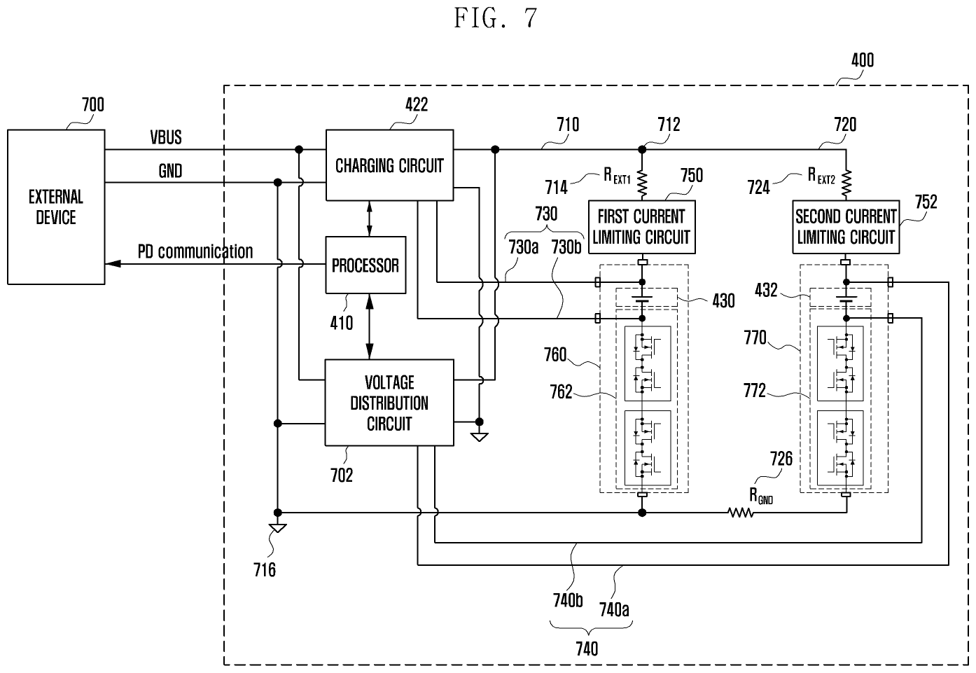

According to various embodiments, the sensing circuit 424 may identify (or measure) the voltage of the second battery 432. For example, the sensing circuit 424 may detect the voltage of the second battery 432 through an electrical path connected to the second battery 432 (e.g., a fourth electrical path 540 in FIG. 5). For example, when the voltage of the second battery 432 reaches a second designated voltage, the sensing circuit 424 may provide state of charge (SOC) information of the second battery 432 to the processor 410. As an example, the second designated voltage may include a reference voltage for determining a time point of switching the charging mode of the second battery 432 or a maximum charging voltage of the second battery 432. For example, the first designated voltage and the second designated voltage may be the same or different. For example, the sensing circuit 424 may be included in a voltage distribution circuit (e.g., a voltage distribution circuit 702 of FIG. 7). As an example, the voltage distribution circuit (e.g., the voltage distribution circuit 702 of FIG. 7) may supply the first battery 430 and/or the second battery 432 with power supplied from an external electronic device (e.g., an external electronic device 700 of FIG. 7) through a direct charging method.

According to various embodiments, the processor 410 may control the charging circuit 422 based on the SOC information of the second battery 432 provided from the sensing circuit 424. According to an embodiment, when receiving the SOC information of the second battery 432 from the sensing circuit 424, the processor 410 may determine that the charging mode of the second battery 432 should be switched. For example, the processor 410 may control the charging circuit 422 to reduce a current supplied to the second battery 432. For example, the processor 410 may transmit a first control signal for controlling the charging current to the charging circuit 422.

According to various embodiments, when the voltage of the second battery 432 reaches a third designated voltage, the sensing circuit 424 may provide charging start information of the second battery 432 to the processor 410. As an example, the third designated voltage may include a voltage predefined to determine the start of charging of the second battery 432. For example, the third designated voltage may be configured to be equal to or lower than the second designated voltage.

According to an embodiment, when receiving the charging start information of the second battery 432 from the sensing circuit 424, the processor 410 may determine that the charging of the second battery 432 should start. For example, the processor 410 may control the charging circuit 422 to increase the current supplied to the second battery 432. For example, the processor 410 may transmit a second control signal for controlling the charging current to the charging circuit 422.

According to an embodiment, the charging circuit 422 may adjust the magnitude of a current (e.g., the magnitude of CC) providing the first battery 430 and/or the second battery 432 based on the second control signal for controlling the charging current provided from the processor 410 while the charging circuit 422 is driven in the CC charging mode. For example, the charging circuit 422 may increase the magnitude of the current (e.g., the magnitude of the CC) providing the first battery 430 and/or the second battery 432 by a designated increased level, based on the second control signal.

According to various embodiments, the electronic device 400 may receive power from an external device (e.g., a power adapter) including a charging control function. According to an embodiment, the processor 410 may select a charging method (e.g., general charging, direct charging, or rapid charging) based on the attribute (e.g., presence or absence of the charging control function) of the external device. For example, when the external device does not provide the charging control function, the processor 410 may select a general charging method. As an example, the charging circuit 422 may control the charging of the first battery 430 and/or the second battery 432 based on the general charging method. For example, when the external device provides the charging control function, the processor 410 may select a direct charging method (or a rapid charging method). As an example, the electronic device 400 may control to supply power to the first battery 430 and/or the second battery 432 through a direct charging circuit based on the direct charging method (or the rapid charging method).

FIG. 5 is a circuit configuration diagram for controlling charging of a battery according to an embodiment of the disclosure. As an example, FIG. 5 may include a circuit configuration for controlling charging of a battery in the electronic device 400.

Referring to FIG. 5, according to various embodiments, the first battery 430 may be arranged on a first electrical path 510 connected from the charging circuit 422 to a ground 516. For example, a first current limiting circuit 550 for preventing an inflow of a current exceeding a designated magnitude into the first battery 430 may be arranged between a first node 512 and the first battery 430 on the first electrical path 510. As an example, in the first electrical path 510, a first resistance 514 (e.g., wiring resistance) due to the first electrical path 510 may be generated.

According to various embodiments, the first battery 430 may include a first protection circuit 562 connected to a second electrode (e.g., a negative (−) electrode) of the first battery 430. For example, the first protection circuit 562 may protect against overdischarge and/or overcharge of the first battery 430. As an example, the first protection circuit 562 may be composed of at least one transistor (e.g., a metal oxide semiconductor field effect transistor (MOSFET)). For example, the first battery 430 and the first protection circuit 562 may be collectively referred to as a first battery pack 560.

According to various embodiments, the second battery 432 may be arranged in parallel with the first battery 430 on the second electrical path 520 which is branched from the first node 512 between the charging circuit 422 and the first battery 430 among the first electrical paths 510 and is connected up to the ground 516. For example, a second current limiting circuit 522 for preventing an inflow of a current exceeding a designated magnitude into the second battery 432 may be arranged between the first node 512 and the second battery 432 on the second electrical path 520. For example, in the second electrical path 520, a second resistance 524 and/or a third resistance 526 (e.g., wiring resistance) due to the second electrical path 520 may be generated.

According to an embodiment, the second battery 432 may include a second protection circuit 572 connected to a second electrode (e.g., a negative (−) electrode) of the second battery 432. For example, the second protection circuit 572 may protect against overdischarge and/or overcharge of the second battery 432. As an example, the second protection circuit 572 may be composed of at least one transistor (MOSFET). For example, the second battery 432 and the second protection circuit 572 may be collectively referred to as a second battery pack 570.

According to various embodiments, the charging circuit 422 may supply power supplied from an external device 500 to the first battery 430 and/or the second battery 432 through the first electrical path 510 and/or the second electrical path 520. According to an embodiment, the charging circuit 422 may identify the voltage of the first battery 430 through the third electrical path 530 branched on the first electrical path 510. For example, the third electrical path 530 may include a first sub-path 530a connecting the charging circuit 422 and a first electrode (e.g., a positive (+) electrode) of the first battery 430 and a second sub-path 530b connecting the charging circuit 422 and a second electrode (e.g., a negative (−) electrode) of the first battery 430. For example, the charging circuit 422 may control the charging mode (e.g., a CC charging mode or a CV charging mode) of the electronic device 400 based on the voltage of the first battery 430.

According to various embodiments, the sensing circuit 424 may identify the voltage of the second battery 432 through a fourth electrical path 540 branched on the second electrical path 520. For example, the fourth electrical path 540 may include a third sub-path 540a connecting the sensing circuit 424 and a first electrode (e.g., a positive (+) electrode) of the second battery 432 and a fourth sub-path 540b connecting the sensing circuit 424 and a second electrode (e.g., a negative (−) electrode) of the second battery 432. For example, when the voltage of the second battery 432 detected through the fourth electrical path 540 reaches a second designated voltage, the sensing circuit 424 may provide state of charge (SOC) information of the second battery 432 to the processor 410. As an example, the SOC information may include information related to a time point at which the second battery 432 is switched from the CC charging mode to the CV charging mode.

According to various embodiments, the processor 410 may transmit a first control signal for controlling the charging current to the charging circuit 422 based on the SOC information of the second battery 432 provided from the sensing circuit 424.

According to various embodiments, when the charging circuit 422 receives a first control signal for controlling a charging current provided from the processor 410 while being driven in a CC charging mode based on the voltage of the first battery 430, the charging circuit 422 may adjust the magnitude of a current (e.g., the magnitude of CC) providing the first battery 430 and/or the second battery. For example, when the first current limiting circuit 550 is driven in the CC charging mode based on the voltage of the first battery 430, the first current limiting circuit 550 may control the amount of a current supplied to the first battery 430 to be kept at a designated magnitude based on the control of the charging circuit 422 and/or the processor 410. For example, when the second current limiting circuit 552 adjusts the amount of a current in the charging circuit 422 based on the voltage of the second battery 432, second current limiting circuit 552 may control the amount of a current supplied to the second battery 432 to be reduced by a designated reduced level based on the control of the charging circuit 422 and/or the processor 410. As an example, the CC charging may be maintained for the first battery 430, and the second battery 432 may be reduced by the designated reduced level as the amount of a current at which the CV charging can proceed.

According to various embodiments, the charging circuit 422 may control the charging mode based on the voltage of the first battery 430. According to an embodiment, when the voltage of the first battery 430 is less than a first designated voltage, the charging circuit 422 may configure the charging mode of the electronic device 400 to be the CC charging mode. By configuring the charging mode of the electronic device 400 to be the CC charging mode, it is possible to supply a current (CC) having a designated magnitude to the first battery 430 and/or the second battery 432. For example, the current of the designated magnitude may include a current of a predefined magnitude for CC charging and/or a current of a magnitude adjusted based on the first control signal provided from the processor 410. According to an embodiment, when the voltage of the first battery 430 reaches the first designated voltage, the charging circuit 422 may switch the charging mode of the electronic device 400 to the CV charging mode.

According to various embodiments, an electronic device (e.g., the electronic device 101 of FIG. 1, the electronic device 200 of FIGS. 2A and 2B, the electronic device of FIGS. 3A, 3B, and 3C, or the electronic device 400 of FIG. 4) may include a charging circuit (e.g., the charging circuit 422 of FIG. 4 or 5); a first battery (e.g., the first battery 430 of FIG. 4 or 5) configured to be arranged on a first electrical path (e.g., the first electrical path 510 of FIG. 5) connected from the charging circuit to the ground; a second battery (e.g., the second battery 432 of FIG. 4 or 5) configured to be arranged in parallel with the first battery on a second electrical path (e.g., the second electrical path 520 of FIG. 5) branched between the charging circuit and the first battery among the first electrical path and connected to the ground; a sensing circuit (e.g., the sensing circuit 424 of FIG. 4 or 5) configured to identify a voltage of the second battery through a fourth electrical path (e.g., the fourth electrical path 540 of FIG. 5) branched on the second electrical path; and a processor (e.g., the processor 410 of FIG. 4 or 5) operatively connected to the sensing circuit and the charging circuit, wherein the charging circuit may identify a voltage of the first battery through a third electrical path (e.g., the third electrical path 530 of FIG. 5) branched on the first electrical path, may receive a current control signal based on the voltage of the second battery through the processor, and may control a magnitude of a current supplied to the first battery and/or the second battery based on the current control signal.

According to various embodiments, the first battery and the second battery may have the same or different capacities.

According to various embodiments, the charging circuit may control a charging mode of the electronic device based on the voltage of the first battery.

According to various embodiments, when the voltage of the first battery is less than or equal to a designated first voltage, the charging circuit may configure the charging mode of the electronic device to be a constant current (CC) mode, and when the voltage of the first battery exceeds the designated first voltage, the charging circuit may switch the charging mode of the electronic device to a constant voltage (CV) mode.

According to various embodiments, when the voltage of the second battery satisfies a designated condition (e.g., a condition for the second battery to switch from the CC mode to the CV mode), the sensing circuit may transmit information related to the state of the second battery to the processor, the processor may transmit a current control signal to the charging circuit based on the information related to the state of the second battery received from the sensing circuit, and the charging circuit may adjust a magnitude of the current supplied to the first battery and/or the second battery to be reduced by a designated reduced level based on the current control signal in a state in which the charging mode of the electronic device is configured to be a CC mode based on the voltage of the first battery.

According to various embodiments, when the voltage of the second battery exceeds a designated second voltage, the sensing circuit may transmit the information related to the state of the second battery to the processor.

According to various embodiments, the third electrical path may include a first sub-path (e.g., the first sub-path 530a of FIG. 5) connected to a positive electrode of the first battery on the first electrical path, and a second sub-path (e.g., the second sub-path 530b of FIG. 5) connected to a negative electrode of the first battery on the first electrical path.

According to various embodiments, the fourth electrical path may include a third sub-path (e.g., the third sub-path 540a of FIG. 5) connected to a positive electrode of the second battery on the second electrical path, and a fourth sub-path (e.g., the fourth sub-path 540b of FIG. 5) connected to a negative electrode of the second battery on the second electrical path.

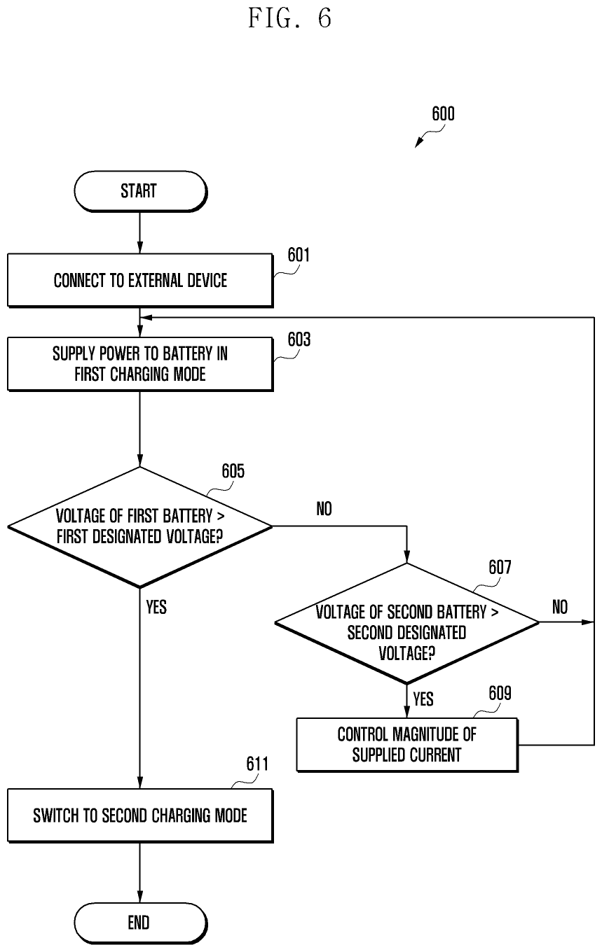

FIG. 6 is a flowchart 600 for controlling charging of a battery in an electronic device according to an embodiment of the disclosure. In the following embodiments, operations may be sequentially performed, but are not necessarily performed sequentially. For example, the order of operations may be changed, and at least two operations may be performed in parallel. As an example, the electronic device may be the electronic device 101 of FIG. 1, the electronic device 200 of FIGS. 2A and 2B, the electronic device 300 of FIGS. 3A, 3B, and 3C, or the electronic device 400 of FIG. 4.

Referring to FIG. 6, according to various embodiments, in operation 601, an electronic device (e.g., the processor 120 or 410 or the power management module 188 or 420) may detect a connection with an external device (e.g., the external device 500 of FIG. 5) for charging a first battery (e.g., the first battery 430) and/or a second battery (e.g., the second battery 432) connected in parallel. According to an embodiment, the electronic device 400 may be connected to the external device 500 in a wired and/or wireless manner.

According to various embodiments, in operation 603, the electronic device (e.g., the charging circuit 422) may supply power supplied from the external device (e.g., the external device 500) to a battery (e.g., the first battery 430 and/or the second battery 432) based on a first charging mode. According to an embodiment, when the voltage of the first battery 430 is less than a first designated voltage, the charging circuit 422 may supply a current of a designated magnitude (CC) to the first battery 430 and/or the second battery 432 based on a first charging mode (e.g., a CC charging mode). As another example, when the voltage of the first battery 430 exceeds the first designated voltage at a time point of connection with the external device 500, the charging circuit 422 may configure the charging mode of the electronic device 400 to be a second charging mode (e.g., a CV mode).

According to various embodiments, in operation 605, the electronic device (e.g., the charging circuit 422) may identify whether the voltage of the first battery (e.g., the first battery 430) exceeds the first designated voltage. According to an embodiment, the charging circuit 422 may periodically or continuously identify the voltage of the first battery 430. For example, the voltage of the first battery 430 may be detected by the charging circuit 422 through the third electrical path 530 connected to the positive electrode of the first battery 430. As an example, the first designated voltage may include a reference voltage for determining a time point of switching the charging mode of the first battery 430 or a maximum charging voltage (or a target voltage) of the first battery 430.

According to various embodiments, when the voltage of the first battery 430 is less than or equal to the first designated voltage (e.g., “NO” in operation 605), in operation 607, the electronic device (e.g., the sensing circuit 424) may identify whether the voltage of the second battery 432 exceeds a second designated voltage. For example, the voltage of the second battery 432 may be detected by the sensing circuit 424 through the fourth electrical path 540 connected to the positive electronic of the second battery 432. For example, the second designated voltage may include a reference voltage for determining a time point of switching the charging mode of the second battery 432 or a maximum charging voltage (or a target voltage) of the second battery 432. According to an embodiment, the sensing circuit 424 may periodically or continuously identify the voltage of the second battery 432.

According to various embodiments, when the voltage of the second battery 432 exceeds the second designated voltage (e.g., “YES” in operation 607), in operation 609, the electronic device (e.g., the processor 410 or the charging circuit 422) may adjust a magnitude of a current provided to the first battery (e.g., the first battery 430) and/or the second battery (e.g., the second battery 432) while being operated in a first charging mode. According to an embodiment, when the voltage of the second battery exceeds the second designated voltage, the sensing circuit may provide SOC information (information related to a time point of switching from a CC mode to a CV mode) of the second battery 432 to the processor 410. For example, when receiving the SOC information of the second battery 432, the processor 410 may determine that the charging mode of the second battery 432 should be switched. Accordingly, the processor 410 may provide a first control signal for controlling the charging current to the charging circuit 422. For example, the charging circuit 422 may reduce a magnitude of a current (e.g., a magnitude of CC) provided to the first battery 430 and/or the second battery 432 by a designated reduced level while operating in the first charging mode based on the first control signal for controlling the charging current. For example, the CC charging may be maintained for the first battery 430, and the second battery 432 may be reduced by the designated reduced level as the amount of a current at which the CV charging can proceed. For example, the first control signal may include a signal requesting to reduce the magnitude of the current.

According to various embodiments, when the voltage of the second battery 432 is less than or equal to the second designated voltage (e.g., “NO” in operation 607), or when the magnitude of the current provided to the battery (e.g., the first battery 430 and/or the second battery 432) is adjusted (e.g., operation 609), in operation 603, the electronic device (e.g., the charging circuit 422) may supply the current of the designated magnitude to the first battery (e.g., the first battery 430) and/or the second battery (e.g., the second battery 432) based on the first charging mode. For example, the current of the designated magnitude may include the current of the predefined magnitude that was supplied to the battery based on the first charging mode or the current of a magnitude adjusted in operation 609.

According to various embodiments, when the voltage of the first battery 430 exceeds the first designated voltage (e.g., “YES” in operation 605), the electronic device (e.g., the charging circuit 422) may switch the charging mode of the electronic device 400 to a second charging mode (e.g., CV charging mode) in operation 611. According to an embodiment, when the voltage of the first battery 430 exceeds the first designated voltage, the charging circuit 422 may determine that the charging mode of the battery (e.g., the first battery 430 and/or the second battery 432) included in the electronic device 400 should be switched. Accordingly, the charging circuit 422 may switch the charging mode of the electronic device 400 from the first charging mode (e.g., the CC charging mode) to the second charging mode (e.g., the CV charging mode).

FIG. 7 is a circuit configuration diagram for controlling charging of a battery through an external device according to an embodiment of the disclosure. As an example, FIG. 7 may include a circuit configuration for controlling charging of a battery in the electronic device 400.

Referring to FIG. 7, according to various embodiments, the first battery 430 may be arranged on a first electrical path 710 connected from the charging circuit 422 to a ground 716. For example, a first current limiting circuit 750 for preventing an inflow of a current exceeding a designated magnitude to the first battery 430 may be arranged between a first node 712 and the first battery 430 on the first electrical path 710. For example, in the first electrical path 710, a first resistance 714 (e.g., wiring resistance) due to the first electrical path 710 may be generated. As an example, the first current limiting circuit 750 may adjust the magnitude of a current flowing into the first battery 430 based on the control of the charging circuit 422, a voltage distribution circuit 702, and/or the processor 410.

According to an embodiment, the first battery 430 may include a first protection circuit 762 connected to a second electrode (e.g., a negative (−) electrode) of the first battery 430. For example, the first battery 430 and the first protection circuit 762 may be collectively referred to as a first battery pack 760.

According to various embodiments, the second battery 432 may be arranged in parallel with the first battery 430 on a second electrical path 720 branched from the first node 712 between the charging circuit 422 and the first battery 430 among the first electrical paths 710 and connected up to the ground 716. For example, a second current limiting circuit 752 for preventing an inflow of a current exceeding a designated magnitude to the second battery 432 may be arranged between the first node 712 and the second battery 432 on the second electrical path 720. For example, in the second electrical path 720, a second resistance 724 and/or a third resistance 726 (e.g., wiring resistance) due to the second electrical path 720 may be generated. As an example, the second current limiting circuit 752 may adjust the magnitude of the current flowing into the second battery 432 based on the control of the charging circuit 422, the voltage distribution circuit 702 and/or the processor 410.

According to various embodiments, the second battery 432 may include a second protection circuit 772 connected to a second electrode (e.g., a negative (−) electrode) of the second battery 432. For example, the second battery 432 and the second protection circuit 772 may be collectively referred to as a second battery pack 770.

According to various embodiments, the processor 410 may select a charging method (e.g., general charging, direct charging, or rapid charging) based on the attribute (e.g., presence or absence of a charging control function) of the external device 700. For example, when the external device 700 does not provide the charging control function, the processor 410 may allow the charging circuit 422 to control the charging of the first battery 430 and/or the second battery 432 based on the general charging method. For example, when the external device 700 provides the charging control function, the processor 410 may control the voltage distribution circuit 702 to supply power to the first battery 430 and/or the second battery 432 based on a direct charging method (or a rapid charging method).

According to various embodiments, the electronic device 400 may operate substantially the same as that of FIG. 5 when charging the first battery 430 and/or the second battery 432 based on the general charging method.

According to various embodiments, the charging circuit 422 may identify the voltage of the first battery 430 through the third electrical path 730 branched on the first electrical path 710. For example, the third electrical path 730 may include a first sub-path 730a connecting the charging circuit 422 and a first electrode (e.g., a positive (+) electrode) of the first battery 430, and a second sub-path 730b connecting the charging circuit 422 and a second electrode (e.g., a negative (−) electrode) of the first battery 430. According to some embodiments, when the electronic device 400 uses the direct charging method (or the rapid charging method), the charging circuit 422 may provide SOC information of the first battery 430 to the processor 410 based on the voltage of the first battery 430. For example, when the voltage of the first battery 430 detected through the third electrical path 730 reaches a first designated voltage, the charging circuit 422 may provide the SOC information of the first battery 430 to the processor 410. For another example, when the voltage of the first battery 430 detected through the third electrical path 730 changes by more than a designated value (e.g., the first designated voltage) or reaches a designated value, the charging circuit 422 may provide the SOC information of the first battery 430 to the processor 410. According to one embodiment, when the electronic device 400 uses the general charging method, the charging circuit 422 may supply power supplied from an external power source to the first battery 430 and/or the second battery 432. For example, when the electronic device 400 uses the general charging method, the charging circuit 422 may configure the charging mode of the electronic device 400 to be a CC charging mode or a CV charging mode based on the voltage of the first battery 430. For example, the charging circuit 422 may adjust the magnitude of the current (e.g., the magnitude of CC) providing the first battery 430 and/or the second battery 432 based on a first control signal for controlling the charging current provided from the processor 410 while the charging circuit 422 is driven in the CC charging mode.

According to various embodiments, when the electronic device 400 uses the direct charging method (or the rapid charging method), the voltage distribution circuit 702 (e.g., the sensing circuit 424 of FIG. 4) may supply power supplied from the external device 700 to the first battery 430 and/or the second battery 432 through the first electrical path 710 and/or the second electrical path 720.

According to various embodiments, the voltage distribution circuit 702 may identify the voltage of the second battery 432 through the fourth electrical path 740 branched on the second electrical path 720. For example, the fourth electrical path 740 may include a third sub-path 740a connecting the voltage distribution circuit 702 and a first electrode (e.g., a positive (+) electrode) of the second battery 432 and a fourth sub-path 740b connecting the voltage distribution circuit 702 and a second electrode (e.g., a negative (−) electrode) of the second battery 432. For example, when the voltage of the second battery 432 detected through the fourth electrical path 740 reaches a second designated voltage, the voltage distribution circuit 702 may provide SOC information of the second battery 432 to the processor 410.

According to various embodiments, the processor 410 may transmit, to the external device 700, a control signal for controlling the charging current based on the SOC information of the first battery 430 provided from the charging circuit 422 and/or the SOC information of the second battery 432 provided from the voltage distribution circuit 702. According to an embodiment, the processor 410 may control the charging circuit 422 or the voltage distribution circuit 702 to supply power to the first battery 430 and/or the second battery 432 based on the charging method of the electronic device 400. For example, when the electronic device 400 uses the direct charging method (or the rapid charging method), the processor 410 may control the voltage distribution circuit 702 to supply power to the first battery 430 and/or the second battery 432. In this case, the charging circuit 422 may operate as a sensing circuit for sensing the voltage of the first battery 430. For example, when the electronic device 400 uses the general charging method, the processor 410 may control the charging circuit 422 to supply power to the first battery 430 and/or the second battery 432. In this case, the voltage distribution circuit 702 may operate as a sensing circuit (e.g., the sensing circuit 424 of FIG. 4) for sensing the voltage of the second battery 432. For example, when the external device 700 includes a charge control function, the electronic device 400 may use the direct charging method (or the rapid charging method) as the charging method, and when the external device 700 does not include the charging control function, the electronic device 400 may use the general charging method as the charging method.

According to various embodiments, the external device 700 may adjust the magnitude of the current (e.g., the magnitude of CC) supplied to the electronic device 400 based on the first control signal (e.g., PD communication) provided from the processor 410. As an example, the magnitude of the current may be reduced by a designated magnitude. A s an example, the first control signal may include a signal requesting a reduction in the amount of current supplied to the electronic device 400.

According to various embodiments, an electronic device (e.g., the electronic device 101 of FIG. 1, the electronic device 200 of FIGS. 2A and 2B, the electronic device 300 of FIGS. 3A, 3B, and 3C, or the electronic device 400 of FIG. 4) may include a first battery (e.g., the first battery 430 of FIG. 4 or 7) configured to be arranged on a first electrical path (e.g., the first electrical path 710 of FIG. 7) connected from a first charging circuit (e.g., the charging circuit 422 of FIG. 4 or 7) to the ground; a second battery (e.g., the second battery 432 of FIG. 4 or 7) configured to be arranged in parallel with the first battery on a second electrical path (e.g., the second electrical path 720 of FIG. 7) branched between the first charging circuit and the first battery among the first electrical path and connected to the ground; the first charging circuit configured to identify a voltage of the first battery through a third electrical path (e.g., the third electrical path 730 of FIG. 7) branched on the first electrical path and to transmit information related to a state of the first battery to a processor when the voltage of the first battery satisfies a designated first condition; a second charging circuit (e.g., the voltage distribution circuit 702 of FIG. 4 or 7) configured to identify a voltage of the second battery through a fourth electrical path (e.g., the fourth electrical path of FIG. 7) branched on the second electrical path and to transmit information related to a state of the second battery to the processor when the voltage of the second battery satisfies a second condition; and a processor (e.g., the processor 410 of FIG. 4 or 5) operatively connected to the first charging circuit and the second charging circuit, wherein the processor may provide a current control signal to an external device based on the information related to the state of the first battery and/or the second battery and the second charging circuit may supply power provided from the external device to the first battery and/or the second battery based on the current control signal.

According to various embodiments, the first battery and the second battery may have the same or different capacities.

According to various embodiments, the first charging circuit may supply the power provided from the external device to the first battery and/or the second battery when the external device satisfies a designated third condition, and the second charging circuit may supply the power provided from the external device to the first battery and/or the second battery when the external device does not satisfy the designated third condition.

According to various embodiments, when the voltage of the first battery exceeds the first designated condition, that is, a first voltage, the first charging circuit may transmit the information related to the state of the first battery to the processor, and when the voltage of the second battery exceeds the designated second condition, that is, a second voltage, the second charging circuit may transmit the information related to the state of the second battery to the processor.

According to various embodiments, the second charging circuit may include a voltage distribution circuit.

According to various embodiments, the third electrical path may include a first sub-path (e.g., the first sub-path 730a of FIG. 7) connected to a positive electrode of the first battery on the first electrical path, and a second sub-path (e.g., the second sub-path 730b of FIG. 7) connected to a negative electrode of the first battery on the first electrical path.

According to various embodiments, the fourth electrical path may include a third sub-path (e.g., the third sub-path 740a in FIG. 7) connected to a positive electrode of the second battery on the second electrical path, and a fourth sub-path (e.g., a fourth sub-path 740b of FIG. 7) connected to a negative electrode of the second battery on the second electrical path.

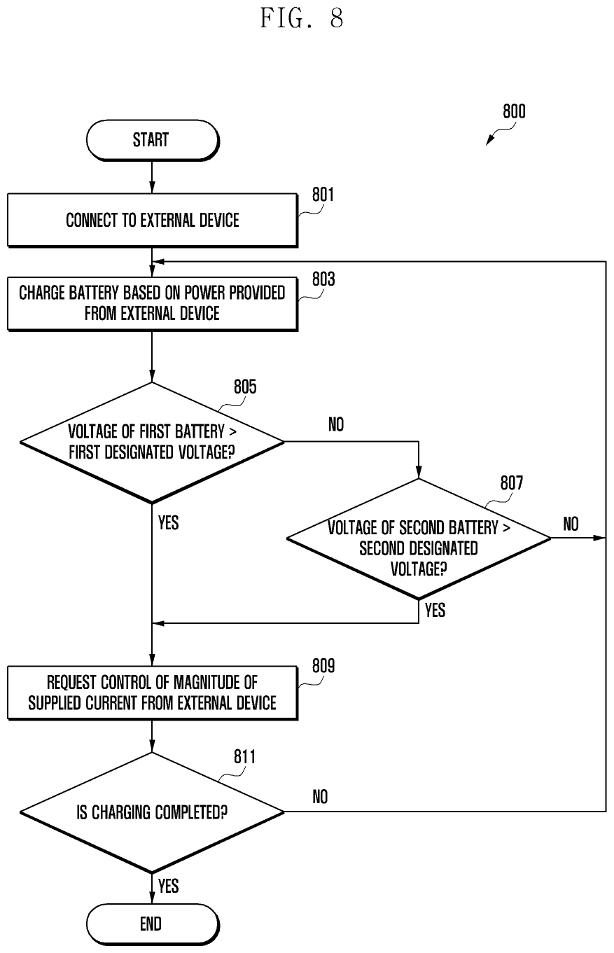

FIG. 8 is a flowchart 800 for controlling charging of a battery through an external device in an electronic device according to an embodiment of the disclosure. In the following embodiments, operations may be sequentially performed, but are not necessarily performed sequentially. For example, the order of operations may be changed, and at least two operations may be performed in parallel. As an example, the electronic device may be the electronic device 101 of FIG. 1, the electronic device 200 of FIGS. 2A and 2B, the electronic device 300 of FIGS. 3A, 3B, and 3C, or the electronic device 400 of FIG. 4.

Referring to FIG. 8, in operation 801, an electronic device (e.g., the processor 120 or 410 or the power management module 188 or 420) may be connected to an external device (e.g., the external device 700 of FIG. 7) for charging a first battery (e.g., the first battery 430) and/or a second battery (e.g., the second battery 432) connected in parallel. According to an embodiment, the electronic device 400 may be connected to the external device 700 in a wired and/or wireless manner. According to an embodiment, the processor 410 may determine that charging is started based on the connection between the electronic device 400 and the external device 700. For example, a state in which the external device 700 is connected by wire and/or wirelessly may include an operation of restarting charging.

According to various embodiments, in operation 803, the electronic device (e.g., the voltage distribution circuit 702) may supply power from the external device (e.g., the external device 700) to charge the first battery 430 and/or the second battery 432. According to an embodiment, when the electronic device 400 uses a direct charging method (or a rapid charging method), the voltage distribution circuit 702 may supply the power supplied from the external device 700 to the first battery 430 and/or the second battery 432. As an example, when the electronic device 400 is connected to the external device 700 that provides a charge control function, the electronic device 400 may control charging of the first battery 430 and/or the second battery 432 in the direct charging method (or the rapid charging method).

According to various embodiments, in operation 805, the electronic device (e.g., the charging circuit 422) may identify whether the voltage of the first battery 430 exceeds a first designated voltage. For example, the voltage of the first battery 430 may be sensed by the charging circuit 422 through the third electrical path 730 connected to the positive electrode of the first battery 430. As an example, the first designated voltage may include a reference voltage for determining a time point for switching the charging mode of the first battery 430 or a maximum charging voltage (or a target voltage) of the first battery 430.

According to various embodiments, when the voltage of the first battery (e.g., the first battery 430) is less than or equal to the first designated voltage (e.g., “NO” in operation 805), in operation 807, the electronic device (e.g., the voltage distribution circuit 702), may identify whether the voltage of the second battery 432 exceeds a second designated voltage. For example, the voltage of the second battery 432 may be sensed by the voltage distribution circuit 702 through the fourth electrical path 740 connected to the positive electrode of the second battery 432. As an example, the second designated voltage may include a reference voltage for determining a time point for switching the charging mode of the second battery 432 or a maximum charging voltage (or a target voltage) of the second battery 432.

According to various embodiments, when the voltage of the second battery (e.g., the second battery 432) is less than or equal to the second designated voltage (e.g., “NO” in operation 807), in operation 803, the electronic device (e.g., the charging circuit 422) may charge the first battery 430 and/or the second battery 432 based on power provided from the external device (e.g., the external device 700).

According to various embodiments, when the voltage of the first battery 430 exceeds the first designated voltage (e.g., “YES” in operation 805) or when the voltage of the second battery 432 exceeds the second designated voltage (e.g., “YES” in operation 807), in operation 809, the electronic device (e.g., the processor 410) may transmit a request signal for controlling the magnitude of the current provided to the first battery 430 and/or the second battery 432 to the external device (e.g., the external device 700). According to an embodiment, when the voltage of the first battery 430 exceeds the first designated voltage, the charging circuit 422 may provide SOC information of the first battery 430 to the processor 410. According to an embodiment, when the voltage of the second battery 432 exceeds the second designated voltage, the voltage distribution circuit 702 may provide SOC information of the second battery 432 to the processor 410. According to an embodiment, when receiving the SOC information of the first battery 430 and/or the second battery 432, the processor 410 may determine that the charging mode of the first battery 430 and/or the second battery 432 is required to be switched. Accordingly, the processor 410 may provide the request signal for controlling the charging current to the external device.

According to various embodiments, in operation 811, the electronic device (e.g., the processor 410 or the voltage distribution circuit 702) may identify whether charging of the battery is completed. According to an embodiment, when the processor 410 is connected to the external device 700 based on a universal serial bus (USB) interface through the connectivity terminal 178, the processor 410 may identify whether the connection with the external device 700 is released through a first pin (e.g., configuration channel (CC)1 pin or CC2 pin) of the USB interface. For example, when the connection with the external device 700 is released, the processor 410 may determine that charging of the battery is completed. According to an embodiment, when receiving a charging completion signal from the external device 700, the processor 410 may determine that charging of the battery is completed. According to an embodiment, when determining that the charging of the first battery 430 and the second battery 432 is completed, the processor 410 may determine that the charging of the battery is completed.

According to various embodiments, when it is determined that the charging is not completed (e.g., “NO” in operation 811), in operation 803, the electronic device (e.g., the processor 410 or the voltage distribution circuit 702) may charge the first battery 430 and/or the second battery 432 based on the power supplied from the external device (e.g., the external device 700). As an example, the current supplied to the first battery 430 and/or the second battery 432 may include a current of which magnitude is reduced by a designated reduced level based on the request signal transmitted to the external electronic device 700 by the processor 410.

According to various embodiments, when it is determined that the charging is completed (e.g., “YES” in operation 811), the electronic device (e.g., the processor 410 or the voltage distribution circuit 702) may complete the charging of the first battery 430 and/or the second battery 432.

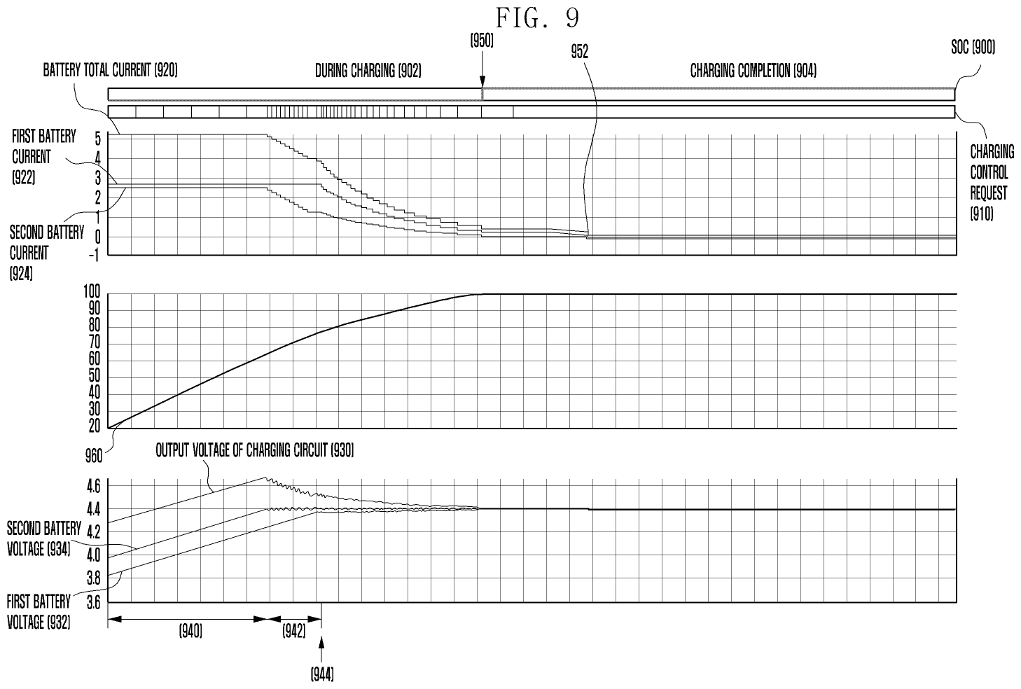

FIG. 9 is a graph illustrating a state of charge (SOC) 900 of a battery according to an embodiment of the disclosure. As in FIG. 5, the following description may include the SOC information of the first battery 430 and/or the second battery 432 according to adjustment of the magnitude of the charging current 920 based on the voltage of the first battery 430 and/or the voltage of the second battery 432 in the charging circuit 422. As an example, the horizontal axis of FIG. 9 represents time (e.g., minute (min)), and the vertical axis represents the magnitude of a current or a voltage.

Referring to FIG. 9, according to various embodiments, the charging circuit 422 may control the charging mode based on a voltage 932 of the first battery 430. According to an embodiment, in the charging circuit 422, when the voltage 932 of the first battery 430 is less than a first designated voltage (e.g., about 4.3V) and the voltage 934 of the second battery 432 is less than a second designated voltage (e.g., about 4.4V) in 940, a current of a designated magnitude may be supplied to the first battery 430 and/or the second battery 432 based on a first charging mode (e.g., CC charging mode) in 922 or 924. For example, the first battery 430 and the second battery 432 may receive the current 920 of the designated magnitude based on the CC charging mode.

According to various embodiments, the charging circuit 422 may adjust the magnitude of the charging current 920 based on the voltage 934 of the second battery 432 while operating in the first charging mode (e.g., CC charging mode) based on the voltage 932 of the first battery 430. According to an embodiment, when the voltage 934 of the second battery 432 exceeds a second designated voltage (e.g., about 4.4V) in 942 while the charging circuit 422 is operated in the first charging mode (e.g., the CC charging mode), the charging circuit 422 may reduce the magnitude of the charging current 920 (e.g., CC) based on the first charging mode (e.g., CC charging mode) by a designated reduced level. For example, the charging circuit 422 may determine that the voltage 934 of the second battery 432 exceeds the second designated voltage (e.g., about 4.4 V) based on a control signal (or charging control request) 910 requesting for controlling the current 920 provided from the processor 410. For example, the charging circuit 422 may reduce the magnitude of the charging current 920 by the designated reduced level so that the amount of the current 924 introduced into the second battery 432 may be reduced. For example, the CC charging based on the current 920 of the designated magnitude may be maintained for the first battery 430, and the second battery 432 may be reduced by the designated reduced level as the amount of a current 920 at which the CV charging can proceed. For example, the processor 410 may transmit the control signal 910 requesting for controlling the current 920 to the charging circuit 422 whenever it is sensed that the voltage 934 of the second battery 432 exceeds the second designated voltage (e.g., about 4.4V) through the sensing circuit 424. For example, the second battery 432 may supply power to an internal circuit (e.g., the processor 410 and the sensing circuit 424) of the electronic device 400 while performing charging based on the charging current 920. Accordingly, changes in which the voltage of the second battery 432 exceeds the second designated voltage based on the charging current 924, becomes lower than the second designated voltage by the power supply to the internal circuit, and exceeds again the second designated voltage based on the charging current 924 may repeatedly occur.

According to various embodiments, as shown in FIG. 9, the electronic device 400 may reduce the magnitude of the charging current 920 by the designated reduced level whenever it is sensed that the voltage 934 of the second battery 432 exceeds the second designated voltage, while operating in the first charging mode based on the voltage 932 of the first battery 430. In this case, the electronic device 400 may obtain an effect as if the electronic device 400 has switched to the second charging mode (e.g., CV mode) from the side of the second battery 432.

According to various embodiments, the charging circuit 422 may switch the charging mode based on the voltage 932 of the first battery 430. According to an embodiment, when the voltage 932 of the first battery 430 exceeds the first designated voltage (e.g., about 4.3V) in 944, the charging circuit 422 may continuously reduce the magnitude of the current supplied to the first battery 430 and/or the second battery 432 based on the second charging mode (e.g., CV charging mode) in 922 or 924.

According to various embodiments, when a state of charge (SOC) 960 of the battery (e.g., the first battery 430 and/or the second battery 432) does not satisfy a designated first reference value (e.g., about 100%) in FIG. 9, the electronic device 400 may output information related to the charging of the battery in 902.

According to various embodiments, the electronic device 400 may output information related to the completion of charging of the battery in 904 when the SOC 960 of the battery (e.g., the first battery 430 and/or the second battery 432) satisfies the designated first reference value (e.g., about 100%). For example, the electronic device 400 may display the information related to the completion of charging of the battery in at least partial area of a display device (e.g., the display device 160 of FIG. 1). For example, the SOC 960 of the battery may be configured based on the voltage of the first battery 430 and/or the second battery 432 and a charging target voltage of the second battery 432. As an example, the designated first reference value may include a predefined reference value to determine a time point of outputting the information related to the completion of charging of the battery. According to an embodiment, the electronic device 400 may continuously charge the battery (e.g., the first battery 430 and/or the second battery 432) even when the SOC 960 of the battery (e.g., the first battery 430 and/or the second battery 432) satisfies the designated first reference value (e.g., about 100%).

According to various embodiments, the electronic device 400 may determine that the charging of the battery is completed when the SOC 900 of the battery (e.g., the first battery 430 and/or the second battery 432) satisfies a second designated reference value (e.g., about 103%) 950. When it is determined that the charging of the battery is completed, the electronic device 400 may stop supplying of the current 920 to the battery (e.g., the first battery 430 and/or the second battery 432) 952.

According to various embodiments, a method of operating an electronic device (e.g., the electronic device 101 of FIG. 1, the electronic device 200 of FIGS. 2A and 2B, the electronic device 300 of FIGS. 3A, 3B, and 3C, or the electronic device 400 of FIG. 4) may include determining a charging mode of the electronic device based on a voltage of a first battery among the first battery (e.g., the first battery 430 of FIG. 4 or 5) and a second battery (e.g., the second battery 432 of FIG. 4 or 5) connected in parallel through an electrical path (e.g., the first electrical path 510 and/or the second electrical path 520); continuously providing a current 920 of a first magnitude through the electrical path when the charging mode of the electronic device is determined to be a first charging mode; and adjusting the magnitude of the current 920 provided through the electrical path to a second magnitude different from the first magnitude when the voltage of the second battery satisfies a designated condition.

According to various embodiments, the first battery and the second battery may have the same or different capacities.

According to various embodiments, the determining of the charging mode may include configuring the charging mode of the electronic device to be the first charging mode when the voltage of the first battery is less than or equal to a first designated voltage, and configuring the charging mode of the electronic device to be a second charging mode different from the first charging mode when the voltage of the first battery exceeds the first designated voltage.

According to various embodiments, the first charging mode may include a constant current (CC) mode, and the second charging mode may include a constant voltage (CV) mode.

According to various embodiments, the adjusting of the magnitude of the current 920 may include adjusting the magnitude of the current 920 supplied to the first battery and/or the second battery to the second magnitude reduced by a designated reduced level when the voltage of the second battery exceeds the second designated voltage while the electronic device is operating in the first charging mode.

According to various embodiments, an electronic device including a first battery (e.g., a first battery pack or a first cell of a battery) and a second battery (e.g., a second battery pack or a second cell of a battery) connected in parallel may switch the charging mode based on the voltage of the first battery connected to the charging circuit, and may control the magnitude of the current for charging the first battery and/or the second battery based on the voltage of the second battery connected to the sensing circuit, thereby reducing the charging time of the battery.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a charging circuit;
a first battery configured to be arranged on a first electrical path connected from the charging circuit to an electrical ground;
a second battery configured to be arranged in parallel with the first battery on a second electrical path branched between the charging circuit and the first battery among the first electrical path and connected to the electrical ground;
a sensing circuit configured to identify a voltage of the second battery through a fourth electrical path branched on the second electrical path; and
a processor operatively connected to the sensing circuit and the charging circuit,
wherein the charging circuit is configured to:
identify a voltage of the first battery through a third electrical path branched on the first electrical path,
receive a current control signal based on the voltage of the second battery through the processor, and
control a magnitude of a current supplied to the first battery or the second battery based on the current control signal.

2. The electronic device of claim 1, wherein the first battery and the second battery have the same or different capacities.

3. The electronic device of claim 1, wherein the charging circuit controls a charging mode of the electronic device based on the voltage of the first battery.

4. The electronic device of claim 3,
wherein when the voltage of the first battery is less than or equal to a designated first voltage, the charging circuit configures the charging mode of the electronic device to be a constant current (CC) mode, and
wherein when the voltage of the first battery exceeds the designated first voltage, the charging circuit switches the charging mode of the electronic device to a constant voltage (CV) mode.

5. The electronic device of claim 4,
wherein when the voltage of the second battery satisfies a designated condition, the sensing circuit transmits information related to a state of the second battery to the processor,
wherein the processor transmits the current control signal to the charging circuit based on the information related to the state of the second battery received from the sensing circuit, and
wherein the charging circuit adjusts a magnitude of the current supplied to the first battery or the second battery to be reduced by a designated reduced level based on the current control signal in a state in which the charging mode of the electronic device is configured to be the CC mode based on the voltage of the first battery.

6. The electronic device of claim 5, wherein, when the voltage of the second battery exceeds a designated second voltage, the sensing circuit transmits the information related to the state of the second battery to the processor.

7. The electronic device of claim 1, wherein the third electrical path comprises a first sub-path connected to a positive electrode of the first battery on the first electrical path, and a second sub-path connected to a negative electrode of the first battery on the first electrical path.

8. The electronic device of claim 1, wherein the fourth electrical path comprises a third sub-path connected to a positive electrode of the second battery on the second electrical path, and a fourth sub-path connected to a negative electrode of the second battery on the second electrical path.

9. A method for operating an electronic device, the method comprising:
determining a charging mode of the electronic device based on a voltage of a first battery among the first battery and a second battery connected in parallel through an electrical path;
continuously providing a current of a first magnitude through the electrical path when the charging mode of the electronic device is determined to be a first charging mode; and
adjusting the magnitude of the current provided through the electrical path to a second magnitude different from the first magnitude when the voltage of the second battery satisfies a designated condition.

10. The method of claim 9, wherein the first battery and the second battery have the same or different capacities.

11. The method of claim 9, wherein the determining of the charging mode comprises:
configuring the charging mode of the electronic device to be the first charging mode when the voltage of the first battery is less than or equal to a first designated voltage; and
configuring the charging mode of the electronic device to be a second charging mode different from the first charging mode when the voltage of the first battery exceeds the first designated voltage.

12. The method of claim 11, wherein the first charging mode comprises a constant current (CC) mode, and the second charging mode comprises a constant voltage (CV) mode.

13. The method of claim 9, wherein the adjusting of the magnitude of the current comprises:
adjusting the magnitude of the current supplied to the first battery or the second battery to the second magnitude reduced by a designated reduced level when the voltage of the second battery exceeds a second designated voltage while the electronic device is operating in the first charging mode.

14. An electronic device comprising:
a first battery configured to be arranged on a first electrical path connected from a first charging circuit to an electrical ground;
a second battery configured to be arranged in parallel with the first battery on a second electrical path branched between the first charging circuit and the first battery among the first electrical path and connected to the electrical ground;
the first charging circuit configured to identify a voltage of the first battery through a third electrical path branched on the first electrical path and to transmit information related to a state of the first battery to a processor when the voltage of the first battery satisfies a designated first condition;
a second charging circuit configured to identify a voltage of the second battery through a fourth electrical path branched on the second electrical path and to transmit information related to a state of the second battery to the processor when the voltage of the second battery satisfies a second condition; and
a processor operatively connected to the first charging circuit and the second charging circuit,
wherein the processor is configured to provide a current control signal to an external device based on the information related to the state of the first battery or the second battery, and
wherein the second charging circuit is configured to supply power provided from the external device to the first battery or the second battery based on the current control signal.

15. The electronic device of claim 14, wherein the first battery and the second battery have the same or different capacities.

16. The electronic device of claim 14,
wherein the first charging circuit supplies the power provided from the external device to the first battery or the second battery when the external device satisfies a designated third condition, and
wherein the second charging circuit supplies the power provided from the external device to the first battery or the second battery when the external device does not satisfy the designated third condition.

17. The electronic device of claim 14,
wherein when the voltage of the first battery exceeds the first designated condition, which is a first voltage, the first charging circuit transmits the information related to the state of the first battery to the processor, and
wherein when the voltage of the second battery exceeds a designated second condition, which is a second voltage, the second charging circuit transmits the information related to the state of the second battery to the processor.

18. The electronic device of claim 14, wherein the second charging circuit comprises a voltage distribution circuit.

19. The electronic device of claim 14, wherein the third electrical path comprises a first sub-path connected to a positive electrode of the first battery on the first electrical path, and a second sub-path connected to a negative electrode of the first battery on the first electrical path.

20. The electronic device of claim 14, wherein the fourth electrical path comprises a third sub-path connected to a positive electrode of the second battery on the second electrical path, and a fourth sub-path connected to a negative electrode of the second battery on the second electrical path.
